(19) United States
(12) Patent Application Publication
(10) Pub. No.: US 2017/0279294 A1
(43) Pub. Date: Sep. 28, 2017

(54) CHARGING DEVICE, CHARGING SYSTEM, AND ELECTRONIC APPARATUS

(71) Applicant: NEC Corporation, Tokyo (JP)

(72) Inventor: Kenichiro FUJII, Tokyo (JP)

(73) Assignee: NEC Corporation, Tokyo (JP)

(21) Appl. No.: 15/510,972

(22) PCT Filed: Sep. 11, 2015
(86) PCT No.: PCT/JP2015/075844

§ 371 Date: Mar. 13, 2017

(30) Foreign Application Priority Data
Sep. 19, 2014 (JP) 2014-191434

(51) Int. Cl. H02J 7/02; H02J 7/00; H05K 9/00; H02J 50/10

(52) U.S. Cl. CPC H02J 7/025; H02J 50/10; H02J 7/0044; H05K 9/0009

(57) ABSTRACT

The charging device and the charging system include a storage space for storing plate-like electronic apparatuses having power-receiving coils mounted on the end portion, and power-supplying coils which are provided on a surface facing the end portion and generate inductive currents in the power-receiving coils of the electronic apparatuses stored in the storage space.

### TECHNICAL FIELD

The present invention relates to a wireless charging device and a charging system, which charge a secondary battery embedded in an electronic apparatus by an electromagnetic induction action, and an electronic apparatus charged by the charging device and the charging system.

### BACKGROUND ART

An example of a charging device using electromagnetic induction is disclosed in Patent Literature 1.

A charging device disclosed in Patent Literature 1 includes power-supplying coils which generate an AC magnetic field, a power supply unit which applies an AC voltage to the power-supplying coils, and an accommodation body which has two accommodation portions capable of accommodating electronic apparatuses, and the power-supplying coils are installed in the accommodation body.

In addition, in the charging device, the power-receiving coils provided on an electronic apparatus are installed at a center of a plane portion of a secondary battery formed in a plate shape, and these are configured to be inserted into the power-supplying coils in the accommodation portion.

In the charge device, if the electronic apparatuses are accommodated in two of the accommodation portions, inductive cents are generated in the power-supplying coils of the electronic apparatuses by an AC magnetic field generated by the power-supplying coils, and thereby the embedded secondary battery is charged.

### CITATION LIST

### Patent Literature

[Patent Literature 1]

Japanese Unexamined Patent Application, First Publication No. 2013-158148

### SUMMARY OF INVENTION

### Problem to Be Solved By the Invention

Incidentally, in the charging device disclosed in Patent Literature 1, power-receiving coils provided on an electronic apparatus are installed at a center of the plane portion of a secondary battery formed in a plate shape, and power-supplying coils are installed in an accommodation body to be inserted between two of the power-receiving coils.

That is, in the charging device, since it is necessary to dispose two electronic apparatuses apart from each other in an accommodation body in view of the disposition of the power-receiving coils and the power-supplying coils, there is a problem that it is difficult to reduce the overall size of the device.

The present invention has been made in view of the above circumstances, and an object thereof is to provide a charging device and a charging system which can perform wireless charging in a state in which a plurality of electronic apparatuses are stacked and disposed in a storage space of a charging box serving as the accommodation body, and overall sizes of the devices can be reduced, and an electronic apparatus charged by the charging device and the charging system.

### Means for Solving the Problem

A charging device of the present invention includes a storage space which stores plate-like electronic apparatuses having power-receiving coils mounted on the end portion, and power-supplying coils which are provided on a surface facing the end portion and generate inductive currents in the power-receiving coils of the electronic apparatuses stored in the storage space.

In addition, a charging system of the present invention transmits or receives data from a host computer to or from the electronic apparatus via power-receiving coils provided on the electronic apparatus and the power-supplying coils provided on the charging box.

Moreover, an electronic apparatus of the present invention is in a sheet or plate shape as a whole, and is accommodated in the storage space, and thereby power-receiving coils facing power-supplying coils provided in the storage space are mounted on the end portion.

### Advantageous Effects of Invention

According to the present invention, it is possible to reduce the sizes of a charging device and a charging system which charge a plurality of electronic apparatuses.

### BRIEF DESCRIPTION OF DRAWINGS

FIG. 1 is a partially transparent perspective view which shows a charging device according to embodiments of the present invention.

FIG. 2 is a perspective view which shows a charging device according to a first embodiment of the present invention.

FIG. 3 is a partially transparent perspective view which shows a positional relationship between coils in the charging device according to the first embodiment.

FIG. 4 is a cross-sectional view which shows coil disposition at a position indicated by a surface IV in FIG. 2.

FIG. 5 is an enlarged cross-sectional view of a main portion of FIG. 4.

FIG. 6 is a cross-sectional view which shows a modification 1 of the first embodiment.

FIG. 7 is a cross-sectional view which shows a modification 2 of the first embodiment.

FIG. 8 is a cross-sectional view which shows a modification 3 of the first embodiment.

FIG. 9 is a partially transparent perspective view which shows a charging device according to a second embodiment of the present invention.

FIG. 10 is a cross-sectional view which shows a positional relationship between coils in the charging device according to the second embodiment.

FIG. 11 is a perspective view which shows a charging device according to a third embodiment of the present invention.

FIG. 12 is a cross-sectional view at a position indicated by a surface XII in FIG. 11.

FIG. 13 is a plan view which shows a positional relationship between coils in FIG. 12.

### EMBODIMENTS FOR CARRYING OUT THE INVENTION

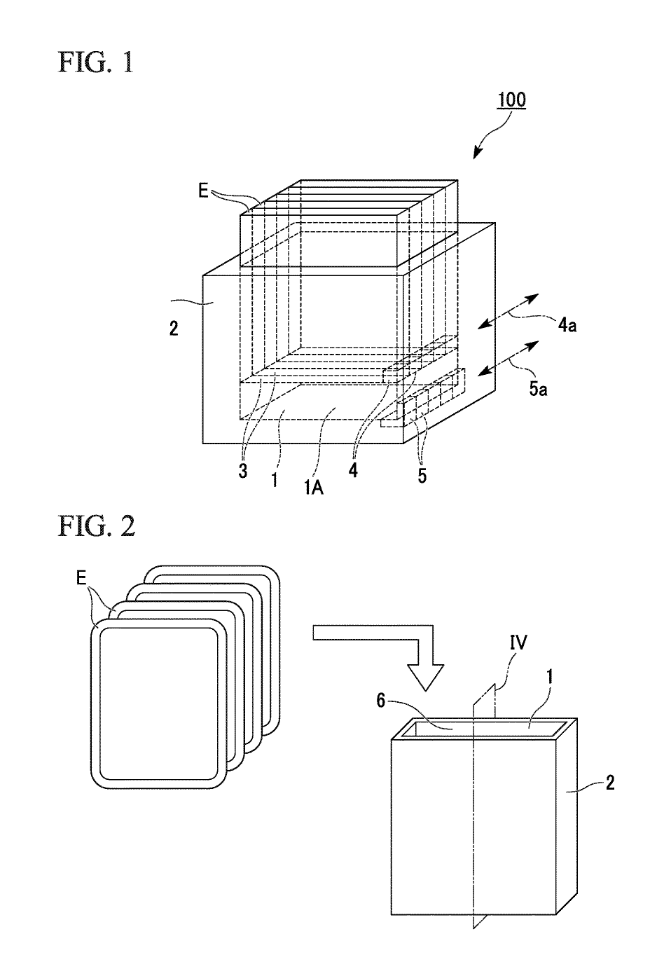

FIG. 1 is a transparent perspective view which shows a minimum configuration of a charging device 100 according to the present invention.

In FIG. 1, a storage space 1 in which a plurality of electronic apparatuses E are detachably accommodated is formed in a charging box 2 and has an upward opening.

Electronic apparatuses E are display terminals formed in a plate shape and have power-receiving coils 4 mounted on a peripheral end portion 3 including an end surface.

Power-supplying coils 5 are provided at a bottom of the storage space 1 in the charging box. The power-supplying coils 5 are provided on an inner surface IA of the storage space 1 facing the end portion 3 of the electronic apparatuses E when the electronic apparatuses E are stored in the storage space 1.

When the electronic apparatuses E are stored in the storage space 1, the power-receiving coils 4 provided at the end portion 3 of the electronic apparatus E are disposed to face the power-supplying coils 5 provided on the charging box 2. Accordingly, due to a magnetic field generated by the power-supplying coils 5 which are primary coils, it is possible to generate inductive currents in the power-receiving coils 4 which are secondary coils, and to charge a secondary battery (not shown) embedded in the electronic apparatus E.

In the charging device 100 configured as described above, the power-receiving coils 4 are mounted on the end portion 3 of the plate-like electronic apparatus E, and the power-supplying coils 5 which generate inductive currents are provided on the inner surface 1A of the storage space 1 facing the power-receiving coils 4 of the electronic apparatus E stored in the storage space 1. With this configuration, the plurality of electronic apparatuses E are accommodated in a stacked manner in the storage space 1 of the charging box, and wireless charging by the power-receiving coils 4 and the power-supplying coils 5 can be performed in this state. Therefore, it is possible to reduce the overall size of the charging device.

### First Embodiment

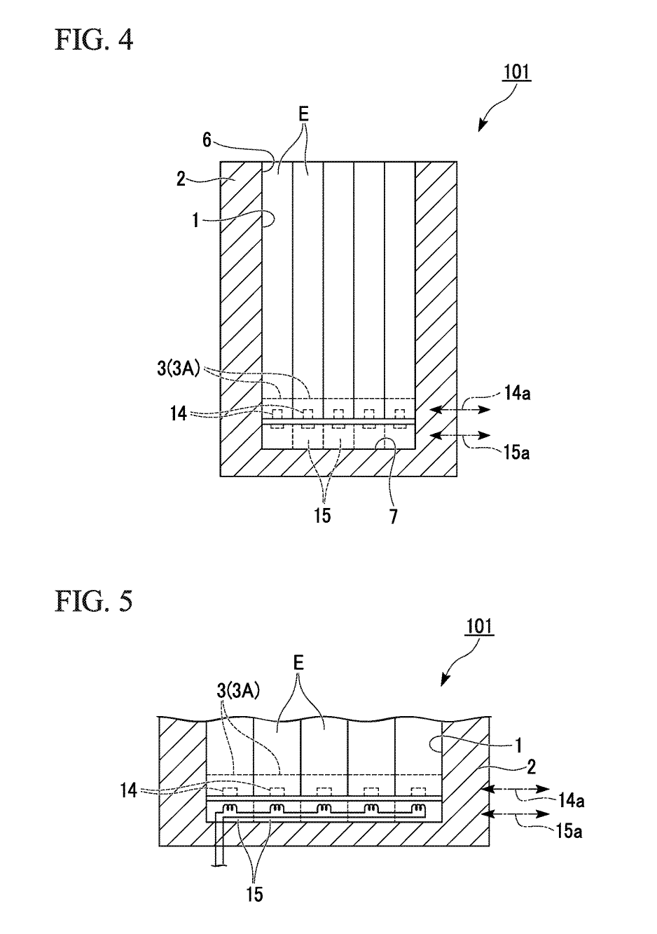

A charging device 101 according to a first embodiment of the present invention will be described with reference to FIGS. 2 to 7.

In these figures, FIGS. 2 to 5 show a more specific charging device 101 than FIG. 1, and a plurality of plate-like electronic apparatuses E are stored in a piled-up state in the storage space 1 of the charging box 2.

The electronic apparatus E is a display terminal formed in a plate shape, and is, for example, a flexible display device used as electronic paper, or the like.

The storage space 1 of the charging box 2 is disposed vertically. The storage space 1 is in a bottomed shape in which an opening 6 is formed at an upper portion of the charging box 2 and a bottom 7 is formed at a lower portion. The charging device 101 has the opening 6 at the upper portion through which the plurality of electronic apparatuses E are put in and taken out from the storage space 1 of the charging box 2.

Here, the plurality of electronic apparatuses E stored in the storage space 1 of the charging box 2 are four or five as illustrated in FIGS. 2 to 5, but the number is not limited.

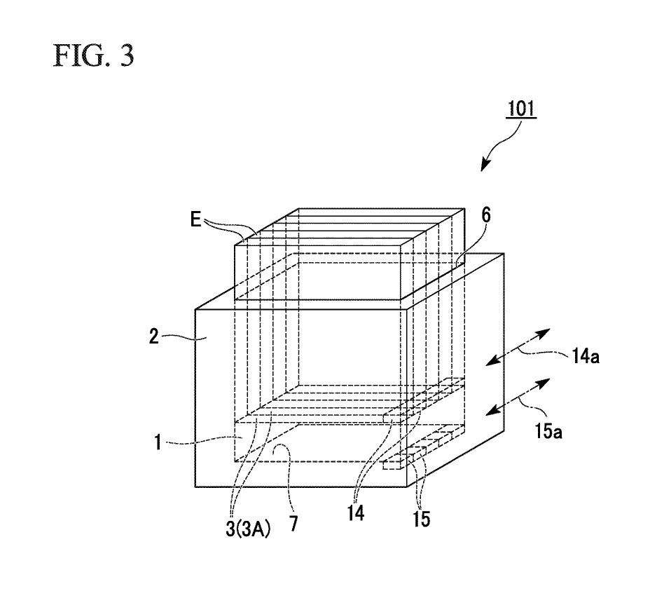

As shown in FIGS. 3 to 5, the power-supplying coils 15 of the first embodiment are provided on a lower surface of the charging box 2 which is the bottom 7 of the storage space 1 and disposed in an arrangement direction 15a in which the plurality of electronic apparatuses E are arranged.

In addition, correspondingly, in a state in which the plurality of electronic apparatuses E are stored side by side in the storage space 1, respective power-receiving coils 14 each provided in the lower side end portion 3 (3A) of the electronic apparatus E are disposed to face the power-supplying coils 15 provided on a charging box 2.

Here, the arrangement direction 15a of the power-supplying coils 15 provided on the charging box 2 and an arrangement direction 14a of the power-receiving coils 14 provided on the electronic apparatus E are set to be in a positional relationship in parallel along with an arrangement direction of the plurality of the electronic apparatuses E when the plurality of the electronic apparatuses E are stored side by side in the storage space 1. Accordingly, the power-supplying coils 15 provided on the charging box 2 and the power-receiving coils 14 provided on the electronic apparatus E are disposed to face each other with a fixed interval at a corresponding place. An interval between the power-receiving coil 14 and the power-supplying coil 15 is preferably narrow in terms of power supply efficiency. On the other hand, the interval is preferably wide in consideration of operability of insertion and removal of the electronic apparatus E or thermal deformation of the electronic apparatus E and the charging device. Therefore, the interval is set to be an optimum value according to performance and use conditions required for the electronic apparatuses E.

The power-supply coils 15 are connected to a power supply via a high frequency generator which converts AC power generated by an AC power supply into AC power of a higher frequency (hereinafter referred to as high frequency) and applies the AC power, but this is omitted in the figure.

The power-supplying coils 15, which are primary coils, are disposed to face the power-receiving coils 14 provided on the electronic apparatus E. The power-supplying coils 15 may be configured as a plurality of coils corresponding to the power-receiving coils 14, or may be configured as a single continuous coil. In addition, the plurality of coils configuring the power-supplying coils 15 may be connected to the high frequency generator in series or each may be connected thereto in parallel.

In the charging device 101 of the first embodiment configured as described above, the power-receiving coils 14 are disposed at the lower side end portion 3 (3A) of the plate-like electronic apparatuses E, and the power-supply coils 15 which generate inductive currents are disposed at the bottom 7 in the storage space 1 facing the power-receiving coils 14 of the electronic apparatuses E. With this configuration, the arrangement direction 14a of the plurality of these power-receiving coils 14 and the arrangement direction 15a of the plurality of these power-supplying coils 15 can be disposed in parallel.

In the charging device 101, the power-supplying coils 15 provided on the charging box 2 and the power-receiving coils 14 provided on the electronic apparatus E are disposed to face each other with a fixed interval. Therefore, due to a magnetic field generated by a primary coil of the power-supplying coils 15, it is possible to generate inductive currents in a secondary coil of the power-receiving coils 14. That is, wireless charging using the power-receiving coils 14 and the power-supplying coils 15 can be performed, and the charging device can be made more compact than conventional devices.

In addition, in the charging device 101, the power-receiving coils 14 provided on the electronic apparatus E are disposed to face the power-supplying coils 15 provided on the charging box 2 with a fixed interval simply by inserting the plurality of electronic apparatuses E into the storage space 1 from the opening 6 of the charging box 2. Therefore, the plurality of electronic apparatuses E can be promptly and easily charged. In addition, when the electronic apparatus E is a flexible display device such as electronic paper, the electronic apparatus can be reliably charged without causing a contact failure such as separation from a contact electrode due to its own deformation as in the case of contact-type power supply.

Moreover, in the charging device 101, both the power-receiving coils 14 of the electronic apparatuses E inserted into the storage space 1 and the power-supplying coils 15 provided on the charging box 2 are positioned at the bottom 7 of the charging box 2. The charging box 2 shields electromagnetic waves generated by the power-receiving and the power-supplying coils 14 and 15, thereby suppressing adverse effects on a worker using the charging device 101.

The charging box 2 itself may be firmed of a shielding body which shields electromagnetic waves generated by the power-supplying coils 15, and the inside of the charging box 2 facing the storage space 1 may be covered with a shielding body which shields electromagnetic waves. In this manner, the way in which the shielding body is set in the charging box 2 is not particularly limited.

(Modification 1)

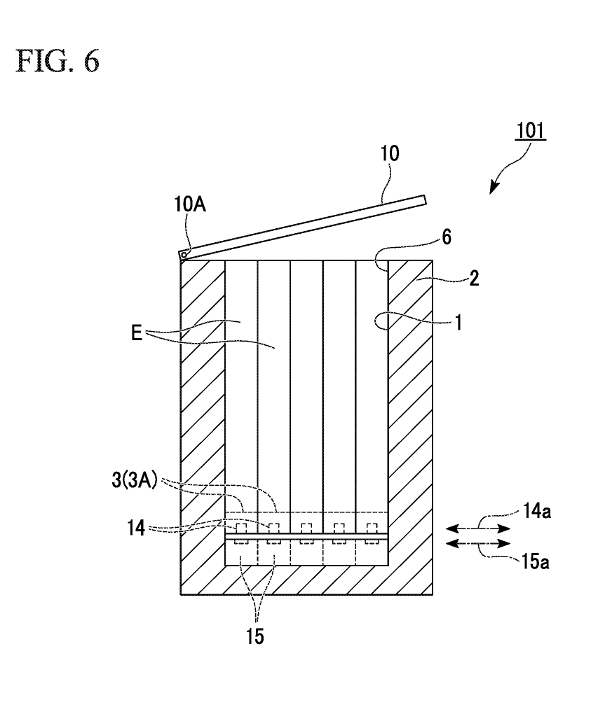

In the charging device 101, the opening 6 of the storage space 1 is open, but, as shown in FIG. 6, a lid 10 which is rotatable about an axis 10A may be provided at the opening 6. This lid 10 is formed of a shielding body, and when the opening 6 is closed, electromagnetic waves generated by the power-receiving coils 14 and the power-supplying coils 15 are effectively shielded.

(Modification 2)

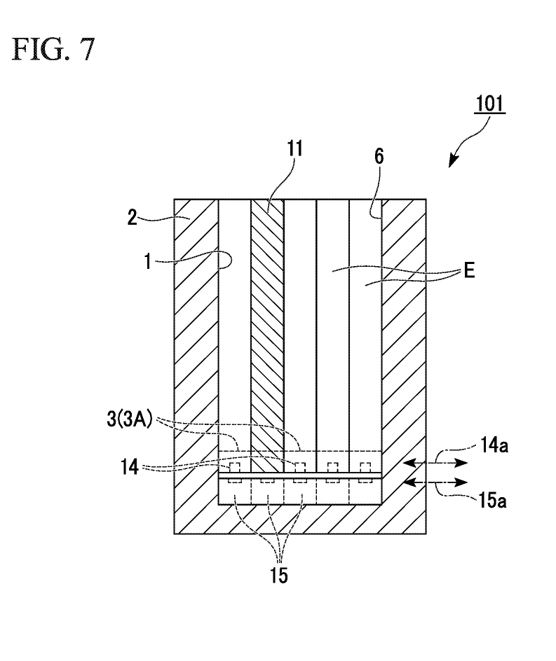

In the charging device 101, the plurality of electronic apparatuses E are stored in the storage space 1. When a predetermined number of electronic apparatuses E are not stored, as shown in FIG. 7, a dummy sheet 11 in the same planar shape as the electronic apparatus E may be stored. By accommodating the dummy sheet 11, no gap is formed between the electronic apparatuses E, and thus it is possible to prevent the electromagnetic waves generated by the power-receiving coils 14 and the power-supplying coils 15 from leaking to the outside. Moreover, by using a hard material such as a metal as the dummy sheet 11, even if the electronic apparatus E is a flexible device such as the electronic paper, the electronic apparatus can be more stably supported in the storage space. The dummy sheet 11 is desirably formed of a magnetic shielding material.

(Modification 3)

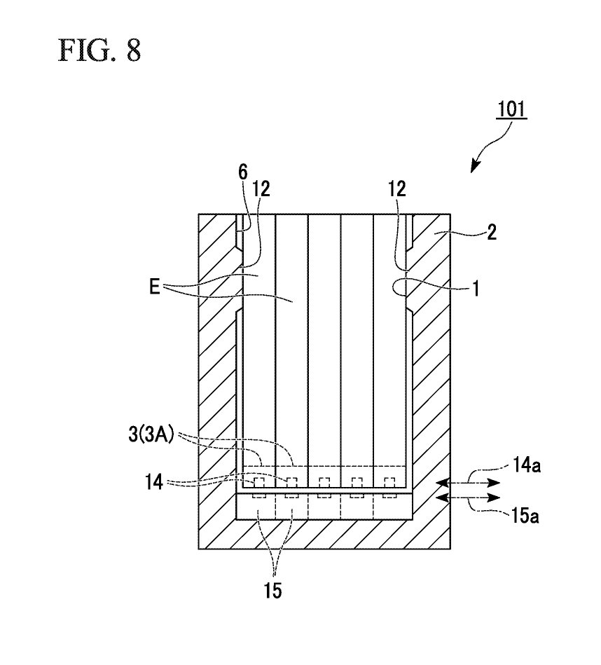

In the charging device 101, to prevent generation of a gap between the electronic apparatuses E, as shown in FIG. 8, a shielding guide 12 for positioning the electronic apparatuses E in the storage space 1 and bringing the electronic apparatuses E into close contact may be provided on an inner surface of the charging box 2 facing the storage space 1.

### Second Embodiment

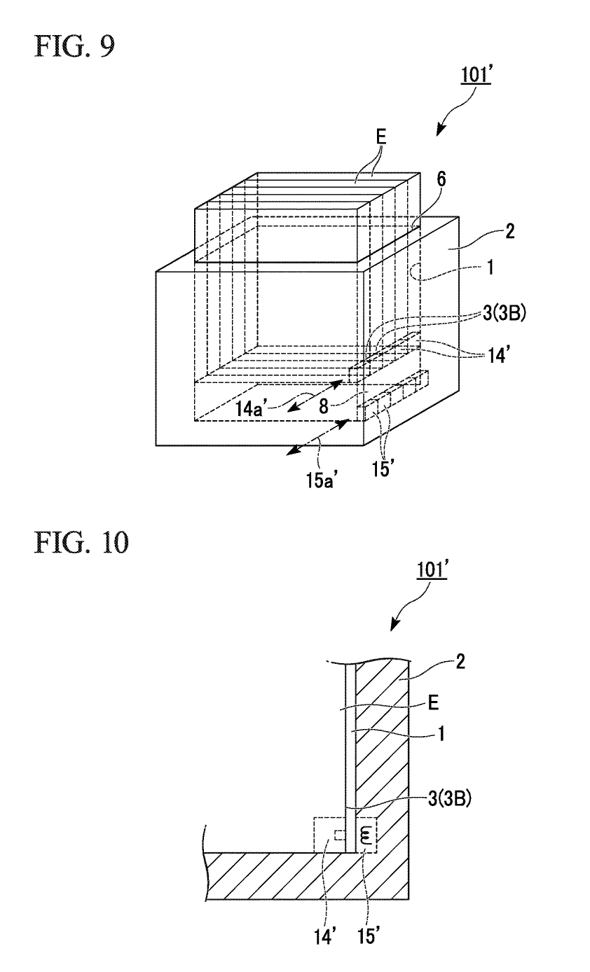

A charging device 101′ according to a second embodiment of the present invention will be described with reference to FIGS. 9 and 10.

The charging device 101′ according to the second embodiment differs from the charging device 101 according to the first embodiment in installation positions of power-receiving coils 14′ provided on an electronic apparatus E and power-supplying coils 15′ provided on a charging box 2.

Specifically, as shown in FIGS. 9 and 10, the power-supplying coils 15′ of the second embodiment are provided on an inner surface of the charging box 2 serving as a side wall portion 8 of the storage space 1, and are disposed in an arrangement direction 15a′ in which electronic apparatuses E are arranged.

Correspondingly, when a plurality of electronic apparatuses E are stored side by side in the storage space 1, each of the power-receiving coils 14′ provided at side end portions 3 (3B) of the electronic apparatuses E is disposed to face one of the power-supplying coils 15′ provided on the charging box 2. The arrangement direction 15a′ of the power-supplying coils 15′ provided on the charging box 2 and the arrangement direction 14a′ of the power-receiving coils 14′ provided on the electronic apparatus E are set to be in a positional relationship in which they are arranged in parallel in a direction in which the electronic apparatuses E are arranged. With this configuration, the power-supplying coils 15′ provided on the charging box 2 and the power-receiving coils 14′ provided on the electronic apparatus E are disposed to face each other with a fixed interval at corresponding positions.

In the charging device 101′ of the second embodiment configured as described above, the power-receiving coils 14′ are disposed at the side end portion 3 (3B) of the plate-like electronic apparatuses E, and the power-supplying coils 15′ which generate inductive currents are disposed at a side wall portion 8 in the storage space 1 facing the power-receiving coils 14′ of the electronic apparatuses E. With this configuration, it is possible to dispose the arrangement direction 14a′ of the plurality of these power-receiving coils 14′ and the arrangement direction 15a′ of the plurality of these power-supplying coils 15′ in parallel.

In the charging device 101′, the power-supplying coils 15′ provided on the charging box 2 and the power-receiving coils 14′ provided on the electronic apparatus E are disposed to face each other with a fixed interval. Accordingly, due to a magnetic field generated by a primary coil of the power-supplying coils 15′, it is possible to generate inductive currents in a secondary coil of the power-receiving coils 14′. That is, wireless charging using the power-receiving coils 14′ and the power-supplying coils 15′ can be performed, and the charging device can be made more compact than conventional devices.

In addition, in the charging device 101′, the power-receiving coils 14′ provided on the electronic apparatus E and the power-supplying coils 15′ provided on the charging box are disposed to face each other with a fixed interval simply by inserting the plurality of electronic apparatuses E into the storage space 1 from the opening 6 of the charging box 2. Therefore, the plurality of electronic apparatuses E can be promptly and easily charged.

In addition, in the charging devices 101 and 101′ of the first and second embodiments, the power-supplying coils 5 and 15′ are provided at the bottom 7 of the storage space 1 or at one end portion of the side wall portion 8. However, the invention is not limited thereto, and the power-supplying coils 5 and 15′ may be provided in parallel to each other at two places of the one end portion and the other end portion positioned at an opposite side to the one end portion. Due to these two places of the power-supplying coils 5 and 15′, it is possible to store the electronic apparatuses E in the storage space 1 without concern for a direction.

Furthermore, the power-receiving coils 4 provided on the electronic apparatus E may be provided at two lower corner portions rather than one corner portion of the end portion 3 (3A, 3B) positioned under the electronic apparatuses E. This also makes it possible to store the electronic apparatuses E in the storage space 1 without concern for a direction.

### Third Embodiment

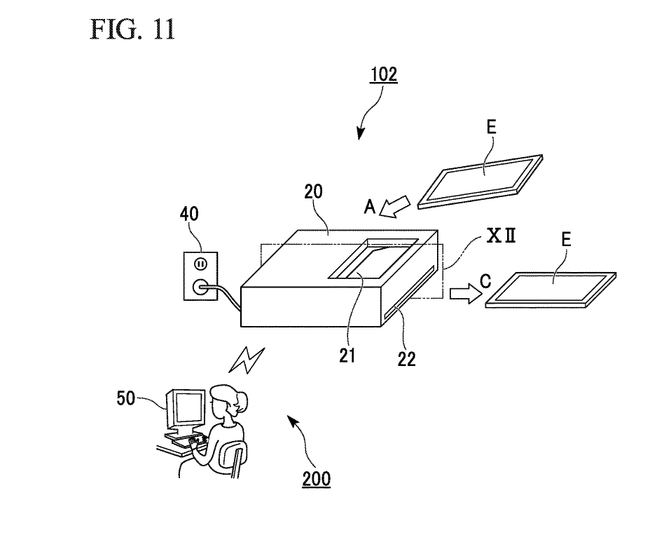

A charging device 102 according to a third embodiment of the present invention will be described with reference to FIGS. 11 to 13.

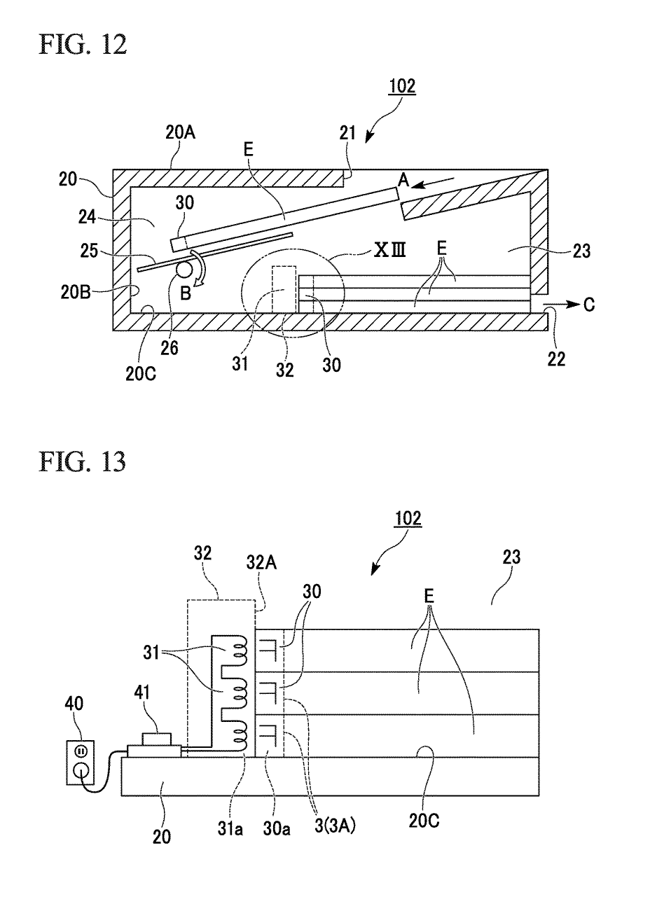

As shown in FIGS. 11 and 12, the charging device 102 according to the third embodiment differs from the charging devices 101 and 101′ according to the first and second embodiments in an arrangement state of the electronic apparatuses E in storage space and provision of a guide mechanism which guides the electronic apparatuses E.

Specifically, a charging box indicated by a reference numeral 20 includes an upper opening 21 serving as an entrance for putting the electronic apparatuses E in, a lower opening 22 provided below the upper opening 21 and serving as an exit for taking the electronic apparatuses E out, and a guide mechanism 24 for guiding the electronic apparatuses E to a storage space 23 inside the charging box 20 from the upper opening 21.

In the storage space 23 of the charging box 20, a plurality of electronic apparatuses E are vertically arranged, that is, the electronic apparatuses E are vertically stacked in a horizontal state.

The upper opening 21 is formed on an upper surface 20A of the charging box 20, and the electronic apparatuses E are inserted into the charging box 20 in an inclined direction indicated by an arrow A.

The lower opening 22 is formed at a side portion 20B of the charging box 20 and is provided at a position facing one side surface of the electronic apparatus E in a horizontal state in the storage space 23, and the electronic apparatus E is taken out in an arrow C direction through the lower opening 22.

The guide mechanism 24 includes a guide board 25 which vertically arranges the electronic apparatuses E put in through the upper opening 21 in the storage space 23, as shown in FIG. 12.

The guide board 25 is provided to be rotatable about a horizontal axis 26, and (the right end) is biased upward by a spring mechanism which is not shown. The guide board 25 is disposed in an inclined state along the arrow A as shown in FIG. 12 in a state in which no electronic apparatuses E are placed thereon.

The guide board 25 rotates about the horizontal axis 26 in a clockwise direction indicated by an arrow B against a biasing force of the spring member (not shown) due to a weight of the electronic apparatus E, when the electronic apparatus E put in through the upper opening 21 is received by the upper surface thereof. By this rotation, the electronic apparatus E placed on the guide board 25 is guided to slide down into the storage space 23. After guiding the electronic apparatus E into the storage space 25, the guide board 25 returns to an initial position shown in FIG. 12 due to the biasing force of the spring member.

The storage space 23 is formed on a bottom surface 20C of the charging box 20 and the electronic apparatuses E guided via the guide board 25 of the guide mechanism 24 are vertically stacked in a horizontal state.

The electronic apparatuses E are stacked and stored on the bottom surface 20C of the charging box 20, and charging (to be described below) is performed. Then, the electronic apparatuses E are taken out to the outside in a horizontal direction indicated by an arrow C via the lower opening 22 formed at the side portion 20B of the charging box 20. One of the stacked electronic apparatuses E at the lowermost stage is taken out from the lower opening 22 in turn.

Power-receiving coils 30 are provided in the electronic apparatuses E and a power-supplying coil 31 is provided in the storage space 23 of the charging box 20.

The power-receiving coils 30 of the electronic apparatuses E are provided at the lower side end portion 3 (3A) of the electronic apparatuses E, and are disposed in an arrangement direction 30a of the electronic apparatuses E stacked in the storage space 23.

The power-supplying coils 31 are provided on a vertical support surface 32 of a support block 32 installed at the bottom 20C of the charging box 20 as shown in FIG. 13. The power-supplying coils 31 are disposed in an arrangement direction 31a of the stacked electronic apparatuses E.

As a result, when the plurality of electronic apparatuses E are stacked and stored in the storage space 23, each of the power-receiving coils 30 provided in the lower side end portion 3 (3A) of the electronic apparatus E is disposed to face one of the power-supplying coils 31 provided on the charging box 20.

The arrangement direction 31a of the power-supplying coils 31 provided on the charging box 20 and the arrangement direction 30a of the power-receiving coils 30 provided on the electronic apparatus E are set to be in parallel in a direction in which the electronic apparatuses E are stacked when the electronic apparatuses E are vertically stacked in the storage space 23. As a result, the power-supplying coils 31 provided on the charging box 20 and the power-receiving coils 30 provided on the electronic apparatus E are disposed to face each other with a fixed interval at corresponding places.

The charging device 102, as shown in FIG. 13, includes an AC power supply 40 which generates an AC magnetic field and a high frequency generator 41 which converts an AC voltage generated by the AC power supply 40 into a high frequency and applies it to the power-supplying coils 31. This also applies to the charging devices 101 and 101′ shown in the first and second embodiments.

In the charging device 102 of the third embodiment configured as described above, the power-receiving coils 30 are disposed at the lower side end portion 3 (3A) of the plate-like electronic apparatuses E, and the power-supplying coils 31 which generate inductive currents are disposed on a vertical support surface 32A in the storage space 23 facing the power-receiving coils 30 of the electronic apparatuses E. With this configuration, the arrangement direction 30a of the plurality of power-receiving coils 30 and the arrangement direction 31a of the plurality of power-supplying coils 31 can be disposed in parallel.

At this time, in the charging device 102, the power-supplying coils 31 provided on the charging box 20 and the power-receiving coils 30 provided on the electronic apparatus E are disposed to face each other with a fixed interval. With this configuration, due to a magnetic field generated by the power-supplying coils 31 serving as a primary coil, it is possible to generate inductive currents in the power-receiving coils 30 on a secondary side. That is, wireless charging using the power-receiving coils 30 and the power-supplying coils 31 can be performed and the charging device can be made more compact than conventional devices.

Moreover, in the charging device 102, the power-receiving coils 30 provided on the electronic apparatus E and the power-supplying coils 31 provided on the charging box 20 are disposed to face each other with a fixed interval simply by inserting the plurality of electronic apparatuses E into the storage space 23 from the opening 21 of the charging box 20. Therefore, the plurality of electronic apparatuses E can be promptly and easily charged.

In addition, in the charging device 102, both the power-receiving coils 30 of the electronic apparatuses E inserted into the storage space 23 and the power-supplying coils 31 provided on the charging box 20 are positioned in the charging box 20. Therefore, the charging box 20 shields electromagnetic waves generated by these coils 30 and 31, thereby suppressing adverse effects on a worker using the charging device 101.

In the charging device 102, a charging system 200 which transmits or receives data to or from a host computer 50 with respect to the electronic apparatuses E via the power-receiving coils 30 provided on the electronic apparatus E and the power-supplying coils 31 provided on the charging box 20 may be constructed.

At this time, since a plurality of electronic apparatuses E are stored in the storage space 23 of the charging device 102, it is possible to efficiently transmit or receive data to or from these electronic apparatuses E in a collective manner.

Embodiments of the present invention have been described in detail with reference to the drawings, but a specific configuration is not limited to the embodiments, and design changes and the like within the scope not departing from the gist of the present invention are also included.

Priority is claimed on Japanese Patent Application No. 2014-191434, filed Sep. 19, 2014, the content of which is incorporated herein by reference.

### INDUSTRIAL APPLICABILITY

The present invention can be applied to a charging device and a charging system, which charge a secondary battery embedded in an electronic apparatus, and the secondary battery can be wirelessly charged using inductive currents generated by electromagnetic induction.

### REFERENCE SYMBOLS LIST

1 Storage space

2 Charging box

3 End portion

3A Lower side end portion

3B Side end portion

4 Power-receiving coil

5 Power-supplying coil

6 Opening

7 Bottom

8 Side wall portion

10 Lid

11 Dummy sheet

12 Shielding guide

14 Power-receiving coil

15 Power-supplying coil

20 Charging box

21 Upper opening

22 Lower opening

23 Storage space

24 Guide mechanism

25 Guide board

26 Horizontal axis

30 Power-receiving coil

31 Power-supplying coil

32A Vertical support surface

41 High frequency generator

100 Charging device

101 Charging device

102 Charging device

200 Charging system

E Electronic apparatus

1. A charging device comprising:
a storage space which stores plate-like electronic apparatuses having power-receiving coils mounted on the end portion; and
power-supplying coils which are provided on a surface facing the end portion and generate inductive currents in the power-receiving coils of the electronic apparatuses stored in the storage space.

2. The charging device according to claim 1,
wherein the storage space is formed in a charging box having the power-supplying coils inside.

3. The charging device according to claim 2,
wherein a plurality of the plate-like electronic apparatuses are stored in a stacked state in the storage space of the charging box.

4. The charging device according to claim 2,
wherein the storage space of the charging box is covered with a shielding body which shields electromagnetic waves generated from the power-supplying coils.

5. The charging device according to claim 4,
wherein the charging box is formed of a shielding body which shields electromagnetic waves generated from the power-supplying coils.

6. The charging device according to claim 1,
wherein the power-supplying coils are disposed to correspond to the power-receiving coils at the end portion of the electronic apparatuses.

7. The charging device according to claim 6,
wherein the power-supplying coils are provided at a bottom of the storage space, and are disposed at intervals in a stacking direction of the electronic apparatuses stored in a stacked state.

8. The charging device according to claim 6,
wherein the power-supplying coils are provided at a side wall portion of the storage space and are disposed at intervals in an arrangement direction of the electronic apparatuses stored in a stacked state.

9. The charging device according to claim 6,
wherein the power-supplying coils are provided at two places of a bottom of the storage space or one end portion of the side wall portion and the other end portion positioned on an opposite side of the one end portion.

10. The charging device according to claim 6,
wherein the power-receiving coils are provided at two corner portions of an end portion positioned under the electronic apparatuses.

11. The charging device according to claim 1,
wherein the storage space has an opening for putting in or taking out the electronic apparatuses, and
the opening is covered with a lid which shields electromagnetic waves generated by the power-supplying coils.

12. The charging device according to claim 1,
wherein a dummy sheet in the same planar shape as the electronic apparatus is stored in the storage space.

13. The charging device according to claim 1,
wherein a shielding guide for positioning and accommodating the electronic apparatuses in the storage space is provided in the charging box.

14. The charging device according to claim 1,
wherein the charging box includes
an upper opening serving as an entrance for putting the electronic apparatuses in,
a lower opening provided below the upper opening and serving as an exit for taking the electronic apparatuses out, and
a guide mechanism for guiding the electronic apparatuses from the upper opening to the storage space,
the guide mechanism has a guide board for vertically stacking the electronic apparatuses put in from the upper opening in the storage space, and
the lower opening is formed at a side portion of the charging box and is provided at a position facing one side surface of the electronic apparatus in a horizontal state.

15. The charging device according to claim 14,
wherein the guide board of the guide mechanism is provided to be rotatable about a horizontal axis, and rotates about the horizontal axis when the electronic apparatus put in through the upper opening is received by an upper surface of the guide board, thereby converting a direction of the electronic apparatus into a direction crossing a surface of the electronic apparatus and guiding the electronic apparatus to the storage space.

16. The charging device according to claim 1, further comprising an AC power supply which generates an AC magnetic field, and a high frequency generator which converts an alternating current generated by the AC power supply into a high frequency and applies this to the power-supplying coils.

17. The charging device according to claim 1,
wherein the power-receiving coils are disposed on an end portion end surface of the electronic apparatuses and the power-supplying coils are disposed at positions facing the power-receiving coils in the storage space.

18. The charging device according to claim 1,
wherein the electronic apparatuses are configured in an elastically deformable sheet form.

19. A charging system comprising:
the charging device according to claim 1,
wherein the charging device is configured to transmit or receive data from a host computer to or from the electronic apparatuses via power-receiving coils provided on the electronic apparatus and the power-supplying coils provided on the charging box.

20. An electronic apparatus accommodated and charged in a storage space of a charging device, having an overall sheet or plate shape, accommodated in the storage space, and thereby having power-receiving coils facing power-supplying coils provided in the storage space mounted on the end portion thereof.
